(19) United States
(12) Patent Application Publication
(10) Pub. No.: US 2026/0255843 A1
(43) Pub. Date: Aug. 27, 2026

(54) DISPLAY DEVICE AND ELECTRONIC DEVICE

(71) Applicant: Samsung Display Co., LTD., Yongin-si (KR)

(72) Inventors: Seock Hwan KANG, Yongin-si (KR); Hyun Eok SHIN, Yongin-si (KR); Sung Hoon YANG, Yongin-si (KR)

(21) Appl. No.: 19/547,803

(22) Filed: Feb. 24, 2026

(30) Foreign Application Priority Data
Feb. 27, 2025 (KR) 10-2025-0026050

(51) Int. Cl. H10K 59/80; H10K 59/35

(52) U.S. Cl. CPC H10K 59/80516; H10K 59/352; H10K 59/80524

(57) ABSTRACT

A display device includes a base substrate, a pixel electrode including a first pixel electrode, a second pixel electrode , and a third pixel electrode arranged on the base substrate, emission layers including a first emission layer, a second emission layer, and a third emission layer which correspond to different colors and are arranged on the first pixel electrode, the second pixel electrode, and the third pixel electrode, respectively, an auxiliary electrode selectively covering the first emission layer among the emission layers and covering an entire top surface of the first emission layer, without covering the second emission layer and the third emission layer, and a counter electrode commonly and continuously covering the first emission layer, the second emission layer, and the third emission layer.

### CROSS-REFERENCE TO RELATED APPLICATIONS

This application claims priority to Korean Patent Application No. 10-2025-0026050, filed on Feb. 27, 2025, and all the benefits accruing therefrom under 35 U.S.C. §119, the content of which in its entirety is herein incorporated by reference.

### BACKGROUND

### 1. Field

Embodiments of the present disclosure relate to a display device and an electronic device including the display device. More particularly, embodiments of the present disclosure relate to a display device including a light-emitting portion and electrodes, and an electronic device including the display device.

### 2. Descriptions of the Related Art

In a display device such as an organic light emitting diode (OLED) display device and a liquid crystal display (LCD) device, a display substrate including a thin film transistor (TFT) and various wirings may be provided, and a display structure including electrodes and emission layers may be formed on the display substrate.

Pixel regions may include a red pixel region, a green pixel region, and a blue pixel region, and image display quality may be influenced by optical properties from each pixel region.

### SUMMARY

According to an aspect of the present disclosure, there is provided a display device having improved optical and display properties.

According to an aspect of the present disclosure, there is provided an electronic device including a display device with improved optical and display properties.

A display device may include a base substrate, a pixel electrode including a first pixel electrode, a second pixel electrode , and a third pixel electrode arranged on the base substrate; emission layers including a first emission layer, a second emission layer, and a third emission layer which correspond to different colors and are arranged on the first pixel electrode, the second pixel electrode, and the third pixel electrode, respectively, an auxiliary electrode selectively covering the first emission layer among the emission layers and covering an entire top surface of the first emission layer, without covering the second emission layer and the third emission layer, and a counter electrode commonly and continuously covering the first emission layer, the second emission layer, and the third emission layer.

In some embodiments, the first emission layer, the second emission layer, and the third emission layer may be a blue emission layer, a green emission layer, and a red emission layer, respectively.

In some embodiments, an area of the first emission layer may be larger than each of an area of the second emission layer and an area of the third emission layer.

In some embodiments, the counter electrode may be a transmissive electrode, and the auxiliary electrode may be a translucent electrode.

In some embodiments, the auxiliary electrode may include at least one of lithium (Li), silver (Ag), magnesium (Mg), aluminum (Al), aluminum-lithium (Al-Li), calcium (Ca), magnesium-indium (Mg-In), silver-magnesium (Ag-Mg), ytterbium (Yb) or silver-ytterbium (Ag-Yb).

In some embodiments, the auxiliary electrode may be disposed between the first emission layer and the counter electrode.

In some embodiments, the auxiliary electrode may be spaced apart from the first emission layer with the counter electrode interposed between the auxiliary electrode and the first emission layer.

In some embodiments, the auxiliary electrode may commonly cover a plurality of the first emission layers.

In some embodiments, a first emission group may be defined by the first emission layers commonly covered by the auxiliary electrode, a second emission group is defined by the second emission layer and the third emission layer facing the first emission group. The first emission group and the second emission group may be alternately and repeatedly arranged.

In some embodiments, the emission layers may include a plurality of the first emission layer, the second emission layer, and the third emission layer, each of which has a rhombus shape. The auxiliary electrode may individually cover each of the first emission layers.

In some embodiments, a resonance light emission may be implemented through the first emission layer, and a non-resonance light emission may be implemented through the second emission layer and the third emission layer.

A display device may include a base substrate, a pixel electrode including a first pixel electrode, a second pixel electrode , and a third pixel electrode arranged on the base substrate, emission layers including first emission layers, second emission layers, and third emission layers which correspond to different colors and are arranged on the first pixel electrode, the second pixel electrode, and the third pixel electrode, respectively, an auxiliary electrode selectively covering the first emissions layers among the emission layers, without covering the second emission layers and the third emission layers, and commonly covering two or more first emission layers among the first emission layers, and a counter electrode commonly and continuously covering the first emission layers, the second emission layers, and the third emission layers.

In some embodiments, a pixel unit may be defined by a first emission layer, a second emission layer, and a third emission layer neighboring each other among the first emission layers, the second emission layers, and the third emission layers, a plurality of the pixel units may be repeatedly arranged, and the auxiliary electrode may extend throughout two or more pixel units of the pixel units .

In some embodiments, the auxiliary electrode may cover an entire top surface of each of the first emission layers.

In some embodiments, the first emission layers may be blue emission layers, the second emission layers may be green emission layers, and the third emission layers may be red emission layers.

In some embodiments, the counter electrode may be a transmissive electrode, and the auxiliary electrode may be a translucent electrode.

In some embodiments, the auxiliary electrode may be disposed between the first emission layers and the counter electrode.

In some embodiments, the auxiliary electrode may be spaced apart from the first emission layers with the counter electrode interposed between the auxiliary electrode and the first emission layers.

An electronic device may include a display device, a memory, and a processor executing data included in the memory to control an operation of the display device. The display device may include a base substrate, a pixel electrode including a first pixel electrode, a second pixel electrode , and a third pixel electrode arranged on the base substrate; emission layers including a first emission layer, a second emission layer, and a third emission layer which correspond to different colors and are arranged on the first pixel electrode, the second pixel electrode, and the third pixel electrode, respectively, an auxiliary electrode selectively covering the first emission layer among the emission layers and covering an entire top surface of the first emission layer, without covering the second emission layer and the third emission layer, and a counter electrode commonly and continuously covering the first emission layer, the second emission layer, and the third emission layer

In some embodiments, the electronic device may include virtual reality or augmented reality glasses, a smartphone, a tablet personal computer (PC), a laptop, a television, a desk monitor, smart glasses, a head-mounted display, a smart watch, or a vehicle display.

According to embodiments of the embodiments of the present disclosures, an auxiliary electrode covering, e.g., a blue emission layer may be formed in addition to a common electrode covering a plurality of emission layers. In some embodiments, a resonance structure may be selectively implemented in a blue pixel by the auxiliary electrode to enhance both color and viewing angle properties.

### BRIEF DESCRIPTION OF THE DRAWINGS

FIG. 1 is a schematic plan view illustrating a display device according to embodiments.

FIG. 2 is a pixel equivalent circuit diagram of a display device according to embodiments.

FIG. 3 is a schematic plan view illustrating a pixel arrangement of a display device according to embodiments.

FIG. 4 is a cross-sectional view illustrating a display device according to embodiments.

FIGS. 5 and 6 are schematic cross-sectional views illustrating light-emitting elements according to embodiments.

FIGS. 7 and 8 are schematic cross-sectional views illustrating light-emitting properties in the light-emitting elements according to embodiments.

FIG. 9 is a schematic cross-sectional view illustrating a display device according to embodiments.

FIGS. 10 to 13 are schematic plan views illustrating a pixel arrangement of a display device according to embodiments.

FIG. 14 is an exploded perspective view of a display device according to embodiments.

FIG. 15 is a block diagram of an electronic device in accordance with an embodiment.

FIG. 16 is a schematic diagram of electronic devices in accordance with various embodiments.

### DETAILED DESCRIPTION

Hereinafter, embodiments of the present invention will be described in more detail with reference to the attached drawings. The same reference numerals can l be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms "on", "connected", "coupled," and the like used herein refer to a direct placement/connection/combination, and also refers to a case where another element is interposed two different elements.

The terms such as "first", "second", "below", "under", "above," "on," and the like are used in a relative sense to distinguish different elements or positions, and do not specify an absolute position or an absolute order.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

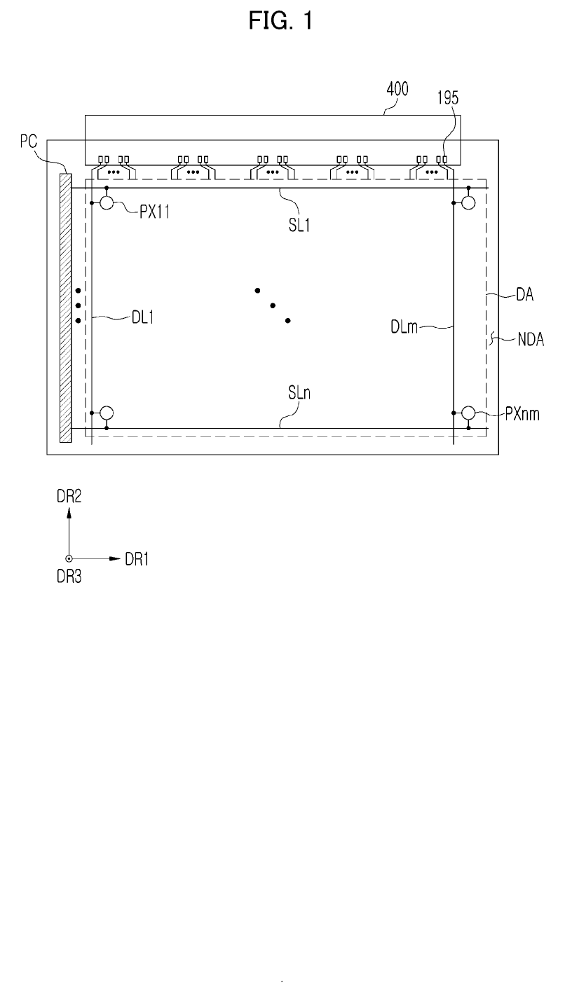

FIG. 1 is a schematic plan view illustrating a display device according to embodiments.

In FIG. 1, a first direction DR1 and a second direction DR2 may refer to two directions parallel to a display surface of a display device and perpendicular to each other. For example, the first direction DR1 may correspond to an X-direction (e.g., a row direction or a width direction) of the display device, and the second direction DR2 may correspond to a Y-direction (a column direction or a length direction) of the display device. A third direction DR3 may be perpendicular to the first direction DR1 and the second direction DR2. The third direction DR3 may correspond to a Z-direction (a thickness direction) of the display device.

In the accompanying drawings, the above definition of the directions may be equally applied.

Referring to FIG. 1, a plurality of pixels PX11 to PXnm may be arranged on ae display area DA of a display device.

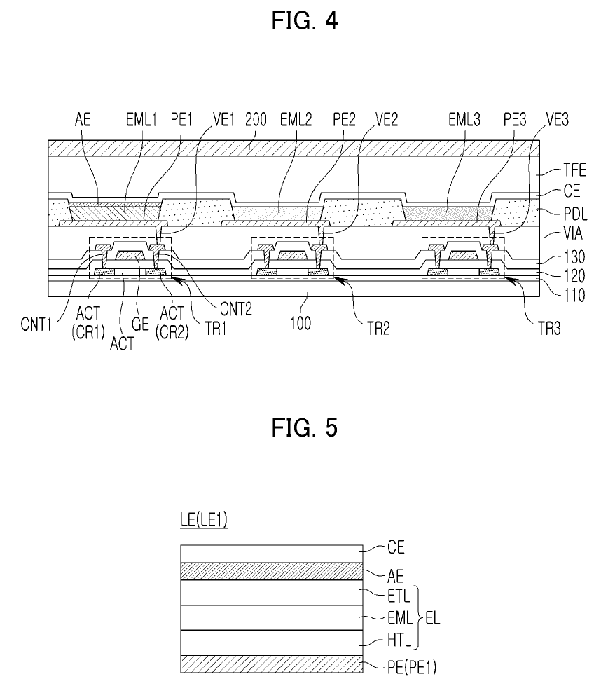

In example embodiments, a pixel circuit including scan lines SL1 to SLn (or gate lines) forming first to nth rows, and data lines DL1 to DLm forming first to mth columns may be arranged on a base substrate 100 (see FIG. 4) of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel driving/switching element including a transistor, and a light-emitting element as described herein. Although not illustrated in detail in FIG. 1 the pixel circuit may further include wirings such as a power line, a ground line, or the like.

FIG. 1 illustrates that the data lines DL1 to DLm extend in the second direction DR2 and the scan lines SL1 to SLn extend in the first direction DR1, but the construction of the data lines and the gate lines is not limited to that illustrated in FIG. 1.

A peripheral circuit PC may be disposed in a non-display area NDA corresponding to a peripheral area of the display area DA. For example, the peripheral circuit PC may include a gate driving circuit. The gate driving circuit may be integrated into the display panel DP by an oxide semiconductor gate (OSG) driver circuit process, an amorphous silicon gate (OSG) driver circuit process, or a polysilicon gate (PSG) driver circuit process.

The peripheral circuit PC may further include a data driver, a gate driver, a light-emitting driver, a power voltage generator, a timing controller, or the like.

The display device may further include a printed circuit board 400. Pads 195 of the pixel circuit may be assembled at one end portion of the non-display area NDA. The printed circuit board 400 may be electrically connected to the pixel circuit through the pads 195. For example, the printed circuit board 400 may be electrically connected to the pads 195 by a heat-compression process using a conductive intermediate structure such as an anisotropic conductive film (ACF).

An integrated circuit (IC) such as a data driving circuit may be disposed on the printed circuit board 400. In some embodiments, an integrated circuit (IC) chip in the form of a chip-on-film (COF) may be mounted on the printed circuit board 400.

Hereinafter, elements /structures of the display device of the present disclosure may be described as an example of an organic light-emitting display device. However, the display device disclosed in the present application may be applied to various types of display devices such as an inorganic light-emitting display device and a quantum dot light-emitting display device,

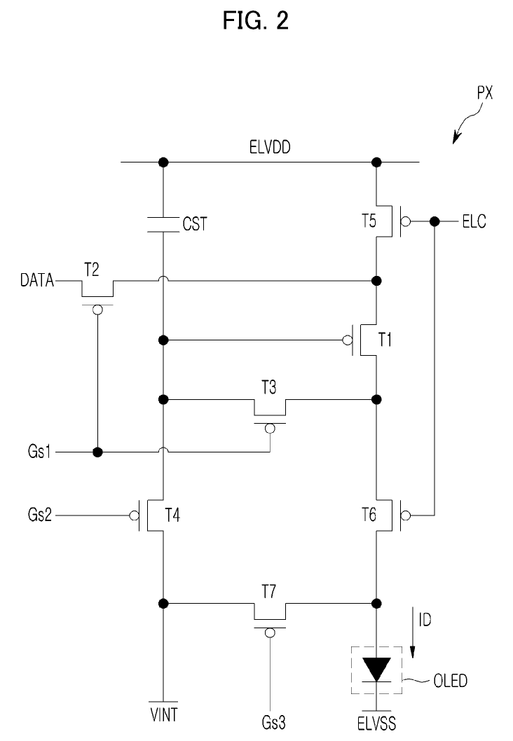

FIG. 2 is a pixel equivalent circuit diagram of a display device according to embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal and a second terminal. The gate terminal may receive the emission control signal ELC. The first terminal may be connected to the first transistor T1. The second terminal may be connected to an organic light-emitting diode OLED. The sixth transistor T6 may transfer the driving current ID to the organic light emitting diode OLED in response to the emission control signal ELC.

The seventh transistor T7 may include a gate terminal, a first terminal and a second terminal. The gate terminal may receive a third gate signal Gs3. The first terminal may be connected to an organic light-emitting diode OLED. The second terminal may receive the initialization voltage VINT. The seventh transistor T7 may initialize the organic light-emitting diode OLED.

The storage capacitor CST may include a first terminal and a second terminal. The first terminal may receive the high-power supply voltage ELVDD. The second terminal may be connected to the gate terminal of the first transistor T1,

The organic light-emitting diode OLED may include a first terminal and a second terminal. The first terminal may be connected to the sixth transistor T6. The second terminal may receive a low-power supply voltage ELVSS. The organic light-emitting diode OLED may emit a light based on the driving current ID.

In FIG. 2, a structure of 7T1C including seven thin film transistors and one storage capacitor CST in each pixel PX is illustrated, but the pixel structure of the display device disclosed herein is not limited thereto.

For example, each pixel PX may include two or more transistors and may have a structure such as 2T1C,3T2C,5T2C, 6T2C, or the like.

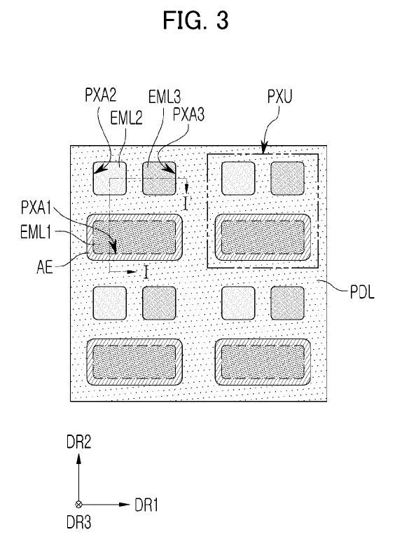

FIG. 3 is a schematic plan view illustrating a pixel arrangement of a display device according to embodiments. Hereinafter, the term "pixel" may refer to a light-emitting area defined by a pixel defining layer PDL. For convenience of descriptions, illustration of a counter electrode CE is omitted in FIG. 3.

Referring to FIG. 3, pixel units PXU may be arranged in the display area DA of the display device. Each pixel unit PXU may include a plurality of pixel areas.

The pixel areas may include a first pixel area PXA1, a second pixel area PXA2, and a third pixel area PXA3. According to embodiments, the first pixel area PXA1, the second pixel area PXA2, and the third pixel area PXA3 may correspond to a blue pixel area, a green pixel area, and a red pixel area, respectively.

An emission layer EML may be disposed in each pixel area. The emission layer EML may include a first emission layer EML1, a second emission layer EML2, and a third emission layer EML3 formed in each of the first pixel area PXA1, the second pixel area PXA2, and the third pixel area PXA3.

The first emission layer EML1, the second emission layer EML2, and the third emission layer EML3 may be emission layers of different respective colors. According to embodiments, the first emission layer EML1, the second emission layer EML2, and the third emission layer EML3 may include a blue organic emission material, a green organic emission material and a red organic emission material, respectively. The organic emission material may include a host material excited by holes and electrons, and a dopant material that may increase luminous efficiency through absorption and emission of energy.

Each pixel unit PXU may include the first pixel area PXA1, the second pixel area PXA2 and the third pixel area PXA3. Accordingly, each pixel unit PXU may include the first emission layer EML1, a second emission layer EML2, and a third emission layer EML3.

In some embodiments, each pixel unit PXU may include one first pixel area PXA1 (one first emission layer EML1), one second pixel area PXA2 (one second emission layer EML2), and one third pixel area PXA3 (one third emission layer EML3). A plurality of pixel units PXU may be repeatedly arranged along the first and second directions DR1 and DR2.

For example, the second pixel area PXA2 (the second emission layer EML2) and the third pixel area PXA3 (the second emission layer EML3) may be adjacent to each other in the first direction DR1 in the pixel unit PXU. In some embodiments, the second pixel area PXA2 (the second emission layer EML2) and the third pixel area PXA3 (the third emission layer EML3) may have substantially the same area or substantially a similar area.

According to embodiments, the first pixel area PXA1 (the first emission layer EML1) may have a larger area than each area of the second pixel area PXA2 (the second emission layer EML2) and the third pixel area PXA3 (the third emission layer EML3). In some embodiments, the first pixel area PXA1 (the first emission layer EML1) may face the second pixel area PXA2 (the second emission layer EML2) and the third pixel area PXA3 (the third emission layer EML3) in the second direction DR2.

As will be described later, the counter electrode CE may commonly and continuously cover the plurality of the pixel units PXU. According to embodiments of the present disclosure, an auxiliary electrode AE may be disposed on the first emission layer EML1. The auxiliary electrode AE may cover only the first emission layer EML1 among the first to third emission layers EML1, EML2 and EML3. The auxiliary electrode AE may selectively cover the first emission layer EML1 without covering the second emission layer EML2 and the third emission layer EML3.

As illustrated in FIG. 3, the auxiliary electrode AE may be individually patterned for each pixel unit PXU and cover the first emission layer EML1. In some embodiments, the auxiliary electrode AE may entirely cover a top surface of the first emission layer EML1.

FIG. 4 is a cross-sectional view illustrating a display device according to embodiments. For example, FIG. 4 is a cross-sectional view taken along a line I-I' of FIG. 3 in the third direction DR3 (a thickness direction).

Referring to FIG. 4, the display device may include first to third transistor structures TR1, TR2 and TR3 formed on the base substrate 100, first to third pixel electrodes PE1, PE2 and PE3 electrically connected to the first to third transistor structures TR1, TR2 and TR3, respectively, and the first to third emission layers EML1, EML2 and EML3 formed on the first to third pixel electrodes PE1, PE2 and PE3, respectively.

The base substrate 100 may serve as a back-plane substrate of a display device. A glass substrate, a ceramic substrate or a plastic substrate may be used as the base substrate 100.

In some embodiments, the base substrate 100 may include a polymer material having transparency and flexibility. In this case, the base substrate 100 may be used in a transparent flexible display device. For example, the base substrate 100 may include a polymer material such as polyimide, polysiloxane, an epoxy resin, an acrylic resin, polyester, or the like. In an embodiment, the base substrate 100 may include polyimide.

A buffer layer 110 may be formed on a top surface of the base substrate 100. Moisture penetrating through the base substrate 100 may be blocked by the buffer layer 110, and diffusion of impurities between the base substrate 100 and structures formed on the base substrate 100 may also be blocked by the buffer layer 110.

The buffer layer 110 may be formed entirely over the display area DA and the non-display area NDA of the base substrate 100 and may entirely cover the top surface of the base substrate 100.

The buffer layer 110 may include, for example, an inorganic insulating material such as silicon oxide, silicon nitride, silicon oxynitride, or the like. These may be used alone or in a combination thereof. In some embodiments, the buffer layer 110 may have a stacked structure including a silicon oxide layer and a silicon nitride layer. The buffer layer 110 may be formed by a deposition process such as a chemical vapor deposition (CVD) process, a sputtering process, an atomic layer deposition (ALD) process, or the like, to include the above-mentioned inorganic insulating material.

The first to third transistor structures TR1, TR2, and TR3 may be disposed on the buffer layer 110. The first transistor structure TR1, the second transistor structure TR2 and the third transistor structure TR3 may be electrically connected to the first pixel electrode PE1, the second pixel electrode PE2, and the third pixel electrode PE3, respectively.

Each of the transistor structures TR1, TR2 and TR3 may include an active layer ACT, a gate insulation layer 120, and a gate electrode GE. The transistor structure TR1, TR2 and TR3 may further include contact electrodes CNT1 and CNT2 connected to the active layer ACT.

The active layer ACT may be disposed on the buffer layer 110 and may be patterned through a photo-lithography process such that the active layer ACT is repeatedly/regularly arranged at each pixel. The active layer ACT may include a silicon compound such as polysilicon or amorphous silicon. A p-type dopant or an n-type dopant may be doped in a partial region of the active layer ACT, and the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on an active layer ACT, and the gate electrode GE may be stacked on the gate insulation layer 120. As illustrated in FIG. 4, the gate insulation layer 120 may be included commonly throughout the first to third transistor structures TR1, TR2 and TR3, or a plurality of the pixel areas.

In an embodiment, the gate insulation layer 120 may partially cover each active layer ACT and may be formed in a pattern shape independently at each of the first to third transistor structures TR1, TR2 and TR3.

The gate electrode GE may overlap the channel region of the active layer ACT in the third direction DR3 (the thickness direction). A scan signal may be transmitted from the scan line through the gate electrode GE.

The gate insulation layer 120 may be formed by the above-mentioned deposition process to include an inorganic insulating material such as silicon oxide, silicon nitride, silicon oxynitride, or a metal oxide.

In some embodiments, a p-type dopant or an n-type dopant may be injected into the active layer ACT by an ion implantation process using the gate electrode GE as an ion implantation mask. Accordingly, a first contact region CR1 and a second contact region CR2 may be formed on one side portion and the other side portion of the active layer ACT, respectively. The first contact region CR1 and the second contact region CR2 may correspond to a source region and a drain region, respectively.

A portion of the active layer ACT overlapping the gate electrode GE in the third direction (the thickness direction) and disposed between the first contact region CR1 and the second contact region CR2 may be defined as the channel region.

In some embodiments, the gate insulation layer 120 may be formed in a pattern covering the channel region through an etching process using the gate electrode GE as an etching mask. In an example in which the active layer ACT includes the oxide semiconductor, hydrogen (H) included in an insulating interlayer 130 may be diffused or transferred to the active layer ACT during the formation of the insulating interlayer 130. Accordingly, a carrier concentration may be increased by hydrogen to form the contact regions CR1 and CR2 at the side portions of the active layer ACT.

The insulating interlayer 130 covering the gate electrode GE and the gate insulation layer 120 may be formed on the active layer ACT. The insulating interlayer 130 may be formed by the above-mentioned deposition process to include an inorganic insulating material such as silicon oxide, silicon nitride, silicon oxynitride, or the like. The insulating interlayer 130 may be formed in a single-layered structure or a multi-layered structure including different materials.

The contact electrodes CNT1 and CNT2 which may be in contact with or electrically connected to the active layer ACT may be formed on the insulating interlayer 130.

The contact electrode may include a first contact electrode CNT1 that may be connected to or in contact with the first contact region CR1 of the active layer ACT, and a second contact electrode CNT2 that may be connected to or in contact with the second contact region CR2 of the active layer ACT. In some embodiments, the first contact electrode CNT1 and the second contact electrode CNT2 may serve as a source electrode and a drain electrode, respectively.

According to embodiments, the insulating interlayer 130 may be partially etched to form contact holes. For example, the contact holes exposing each of the first contact region CR1 and the second contact region CR2 may be formed. A metal layer filling the contact holes may be formed on the insulating interlayer 130, and then may be partially etched to form the first contact electrode CNT1 and the second contact electrode CNT2. For example, a data signal may be transferred from the data line through the first contact electrode CNT1.

The gate electrode GE and the contact electrodes CNT1 and CNT2 may include a metal such as Ag, Mg, Al, W, Cu, Ni, Cr, Mo, Ti, Pt, Ta, Nd, Sc, an alloy thereof, or a nitride thereof. The gate electrode GE and the contact electrodes CNT1 and CNT2 may be formed by a deposition process such as a sputtering process.

The gate electrode GE and the contact electrodes CNT1 and CNT2 may be formed in a multi-layered structure (e.g., a Ti layer-an Al layer-a Ti layer).

A via insulation layer VIA covering the contact electrodes CNT1 and CNT2 may be formed on the insulating interlayer 130. The via insulation layer VIA may be substantially provided as a planarization layer of the TFT-array.

The via insulation layer VIA may be partially etched to form a via hole exposing a top surface of the contact electrode (e.g., the second contact electrode CNT2). An electrode layer filling the via hole may be formed on the top surface of the via insulating layer VIA, and then the electrode layer may be partially etched to form the pixel electrodes PE1, PE2 and PE3.

The pixel electrodes PE1, PE2 and PE3 may include via electrode portions VE1, VE2 and VE3 formed in the via insulating layer VIA. The first to third pixel electrodes PE1, PE2 and PE3 may be electrically connected to the first to third transistor structures TR1, TR2 and TR3 through the first to third via electrode portions VE1, VE2 and VE3, respectively.

The via insulation layer VIA may be formed as an organic insulation layer. For example, the via insulation layer VIA may include an organic polymer material such as polyimide, an epoxy resin, an acrylic resin, polyester, a siloxane resin, benzocyclobutene (BCB), or the like. For example, the via insulation layer VIA may be formed by a coating process such as a spin coating process.

The pixel electrodes PE1, PE2 and PE3 may be provided as an anode and may include a high work function conductive material that may promote hole injection.

According to embodiments, the pixel electrodes PE1, PE2 and PE3 may be formed as a translucent electrode or a reflective electrode. In some embodiments, the pixel electrodes PE1, PE2 and PE3 may be formed as the reflective electrode. The pixel electrodes PE1, PE2 and PE3 may include a metal layer including Ag, Mg, Cu, Al, Pt, Pd, Au, Ni, Nd, Ir, Cr, Li, Ca, Mo, Ti, W, In, Sn, Zn, or the like, or an alloy of two or more therefrom.

The pixel electrodes PE1, PE2 and PE3 may have a single-layered structure or a multi-layered structure. In some embodiments, the pixel electrodes PE1, PE2 and PE3 may further include a transparent conductive oxide layer including indium tin oxide (ITO), indium zinc oxide (IZO), zinc oxide (ZO), indium tin oxide (IGZO), or the like. For example, the pixel electrodes PE1, PE2 and PE3 may have a triple-layered structure of ITO/Ag/ITO or ITO/Al/ITO.

A pixel defining layer PDL exposing a top surface of each of the pixel electrodes PE1, PE2 and PE3 may be formed on the via insulating layer VIA. The pixel defining layer PDL may be formed to at least partially expose the top surfaces of the pixel electrodes PE1, PE2 and PE3. The pixel defining layer PDL may cover peripheral portions of the pixel electrodes PE1, PE2 and PE3.

The pixel areas PXA1, PXA2 and PXA3 described herein may be defined by the pixel defining layer PDL. The pixel areas PXA1, PXA2, and PXA3 may be defined by a sidewall of the pixel defining layer PDL, or an edge where the sidewall and a top surface of the pixel defining layer PDL meet each other.

The pixel defining layer PDL may include, for example, an organic material such as a polysiloxane resin, a polyimide resin, an acrylic resin, or the like. The pixel defining layer PDL may include a colorant such as a black pigment/dye dispersed in a resin material.

In some embodiments, the pixel defining layer PDL may have a repeatedly stacked structure of a silicon oxide layer and a silicon nitride layer.

As described herein, the first emission layer EML1, the second emission layer EML2, and the third emission layer EML3 which are limited or patterned in the first pixel area PXA1, the second pixel area PXA2 and the third pixel area PXA3 may be formed on the first pixel electrode PE1, the second pixel electrode PE2, and the third pixel electrode PE3, respectively.

For example, the first emission layer EML1, the second emission layer EML2, and the third emission layer EML3 may be selectively formed on the first pixel electrode PE1, the second pixel electrode PE2, and the third pixel electrode PE3, respectively, by a thermal vaporization deposition using a fine metal mask (FMM).

According to embodiments of the present disclosure, the first emission layer EML1, the second emission layer EML2, and the third emission layer EML3 may correspond to a blue emission layer, a green emission layer, and a red emission layer, respectively.

The counter electrode CE may be formed on the pixel defining layer PDL and cover the emission layers EML1, EML2 and EML3. As described herein, the counter electrode CE may be formed as a common electrode that may be continuously provided commonly in the first to third pixel regions PXA1, PXA2 and PXA3.

The counter electrode CE may be provided as an electron injection electrode or a cathode. The counter electrode CE may include a metal, an alloy, an electrically conductive compound, or the like, having a low work function.

According to embodiments of the present disclosure, the counter electrode CE may be formed as a transmissive electrode. The counter electrode CE may be formed of a transparent conductive oxide layer including ITO, IZO, ZnO, IGZO, ITZO, or the like. The counter electrode CE may be formed by a deposition process such as a sputtering process.

In some embodiments, as will be described herein, a hole transport layer HTL may be disposed between each of the emission layers EML1, EML2 and EML3, and each of the pixel electrodes PE1, PE2 and PE3. An electron transport layer ETL may be disposed between each of the emission layers EML1, EML2 and EML3 and the opposite electrode CE.

As described herein with reference to FIG. 3, the auxiliary electrode AE may be selectively formed on the first emission layer EML1 among the first emission layer EML1, the second emission layer EML2, and the third emission layer EML3.

In some embodiments, the auxiliary electrode AE may be deposited using a mask including an opening corresponding to the first pixel area PXA1 or the first emission layer EML1. For example, the auxiliary electrode AE may be formed using the fine metal mask (FMM) for forming the emission layers EML1, EML2 and EML3. The openings included in the fine metal mask may be aligned with the first pixel areas PXA1, and then a deposition source may be supplied to form the auxiliary electrode AE.

According to embodiments, the auxiliary electrode AE may be disposed between the first emission layer EML1 and the counter electrode CE. The auxiliary electrode AE may entirely cover a top surface of the first emission layer EML1 in a plan view.

The auxiliary electrode AE may be a metal layer including a metallic material. According to embodiments, the auxiliary electrode AE may be a translucent electrode.

For example, the auxiliary electrode AE may include lithium (Li), silver (Ag), magnesium (Mg), aluminum (Al), aluminum-lithium (Al-Li), calcium (Ca), magnesium-indium (Mg-In), silver-magnesium (Ag-Mg), ytterbium (Yb), silver-ytterbium (Ag-Yb), or the like. These may be used alone or in a combination of two or more therefrom.

A resonance structure may be implemented in the first emission layer EML1 or the first pixel area PXA1 by the auxiliary electrode AE.

An encapsulation layer TFE may be formed on the counter electrode CE. The encapsulation layer TFE may protect the emission layers EML from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, or the like), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer, and a second inorganic layer.

In some embodiments, a functional layer 200 may be stacked on the encapsulation layer TFE. The functional layer 200 may include an optical functional layer or a sensor functional layer such as a color filter, a polarizing plate, a touch sensor layer, or the like.

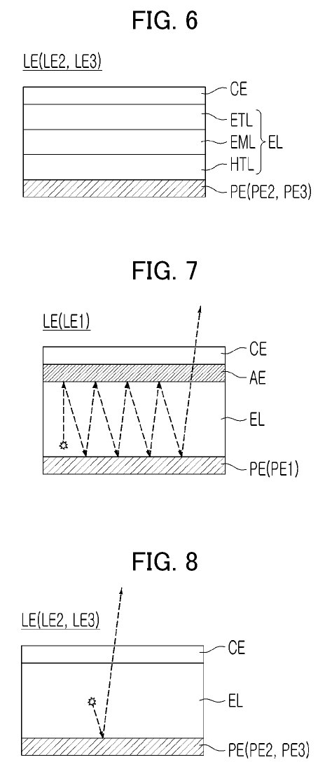

FIGS. 5 and 6 are schematic cross-sectional views illustrating light-emitting elements according to embodiments.

Referring to FIGS. 5 and 6, the light-emitting element LE may include a first light-emitting element LE1, a second light-emitting element LE2 and a third light-emitting element LE3 corresponding to the first pixel area PXA1, the second pixel area PXA2 and the third pixel area PXA3, respectively.

As illustrated in FIG. 5, the first light-emitting element LE1 including the first pixel electrode PE1, a light-emitting portion EL, the auxiliary electrode AE, and the counter electrode CE may be disposed in the first pixel area PXA1.

The light-emitting portion EL may include the hole transport layer HTL, the emission layer EML, and the electron transport layer ETL. According to embodiments, the hole transport layer HTL, the emission layer EML, the electron transport layer ETL, and the counter electrode CE may be sequentially stacked from the top surface of the pixel electrode PE.

For example, the hole transport layer HTL may include a hole transporting material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as Alq3 (tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

In some embodiments, the hole transport layer HTL and the electron transport layer ETL may be formed as a common layer continuously extending over a plurality of the pixel areas of the pixel units PXU.

In some embodiments, a hole injection layer may be further disposed between the pixel electrode PE and the hole transport layer HTL. An electron injection layer may be further disposed between the counter electrode CE and the electron transport layer ETL.

The layers included in the light-emitting portion EL may be formed by a thermal deposition, an evaporation deposition, a vacuum deposition, a spin coating, an inkjet printing, a laser printing, a casting, a laser thermal transfer, or the like.

As described herein, the first light-emitting element LE may include the first emission layer EML1 that may be provided as the blue emission layer. The first light-emitting element LE may further include the auxiliary electrode AE between the counter electrode CE and the light-emitting portion EL.

As illustrated in FIG. 6, the second light-emitting element LE2 may include the second pixel electrode PE2, the light-emitting portion EL and the counter electrode CE. The third light-emitting elements LE3 may include the third pixel electrode PE3, the light-emitting portion EL and the counter electrode CE. In the second light-emitting elements LE2 and the third light emitting device LE3, the auxiliary electrode AE may be omitted, and the counter electrode CE may be directly formed on the light-emitting portion EL.

FIGS. 7 and 8 are schematic cross-sectional views illustrating light-emitting properties in the light-emitting elements according to embodiments.

Referring to FIG. 7, in the first light-emitting element LE1 including the auxiliary electrode AE, resonance emission properties may be implemented in the light-emitting portion EL including the first emission layer EML1.

As illustrated in FIG. 7, a light generated in the light-emitting portion EL may repeatedly resonate between the auxiliary electrode AE and the first pixel electrode PE and may be emitted from the counter electrode CE. Accordingly, luminous efficiency may be increased in a blue pixel having relatively low light-extraction efficiency. In some aspects, light extraction in a deep blue band (e.g., a wavelength band of 460 nm to 470 nm) that may not be easily obtained in a non-resonance blue emission structure may be achieved.

Referring to FIG. 8, non-resonance emission properties may be implemented in the second and third light-emitting elements LE2 and LE3 from which the auxiliary electrode AE is omitted. For example, a light generated in the light-emitting portion EL may be reflected by the second pixel electrode PE2 or the third pixel electrode PE3, and then emitted from the counter electrode CE.

In a green pixel and a red pixel having relatively high luminous efficiency, the auxiliary electrode AE may be omitted, thereby suppressing a decrease in viewing angle that may be caused in the resonance emission structure.

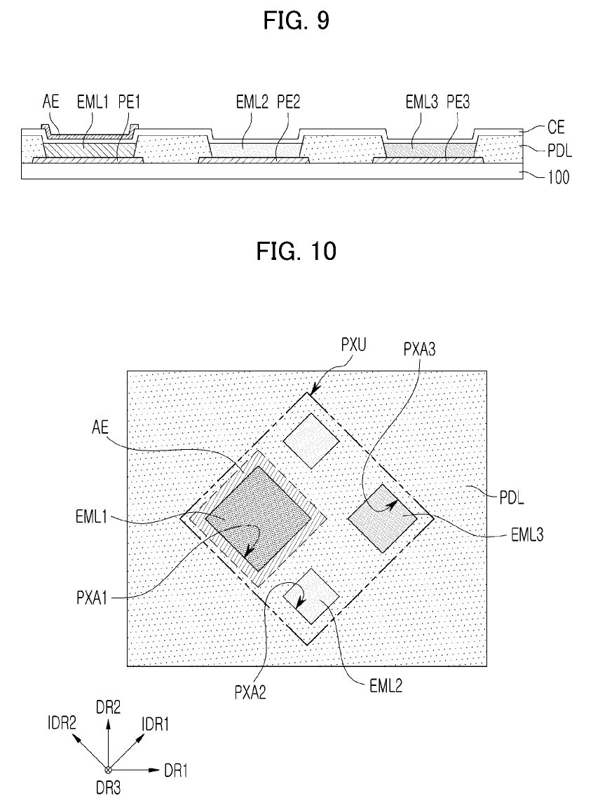

FIG. 9 is a schematic cross-sectional view illustrating a display device according to embodiments. Detailed descriptions on elements and structures substantially the same as or similar to those described with reference to FIGS. 3 and 4 are omitted.

Referring to FIG. 9, in the first light-emitting element LE1 or the first pixel area PXA1, the auxiliary electrode AE may be formed on the counter electrode CE. According to embodiments, the auxiliary electrode AE may be formed directly on a top surface of the counter electrode CE.

Accordingly, a portion of the counter electrode CE may be disposed between the auxiliary electrode AE and the first emission layer EML1 in the first light-emitting element LE1.

In some embodiments, the auxiliary electrode AE may entirely cover a top surface of the first emission layer EML1 on the counter electrode CE.

FIGS. 10 to 13 are schematic plan views illustrating a pixel arrangement of a display device according to embodiments. Detailed descriptions on elements and structures substantially the same as or similar to those described with reference to FIGS. 3 and 4 are omitted.

Referring to FIG. 10, each of the pixel areas PXA1, PXA2 and PXA3 may have substantially a rhombus shape or a diamond shape. Accordingly, each of the emission layers EML1, EML2 and EML3 may also have a rhombus shape or a diamond shape. The pixel unit PXU may also have a rhombus shape or a diamond shape.

The first pixel area PXA1 and the third pixel area PXA3 may face each other in the first direction DR1. The first pixel area PXA1 and the third pixel area PXA3 may be disposed at one corner portion and the other corner portion of the pixel unit PXU in the first direction DR1, respectively. In some embodiments, a pair of the second pixel areas PXA2 may be disposed at one corner portion and the other corner portion of the pixel unit PXU in the second direction DR2, respectively.

Accordingly, one pixel unit PXU may include one first pixel area PXA1 (one first emission layer EML1), two second pixel areas PXA2 (two second emission layers EML2), and one third pixel area PXA3 (one third emission layer EML3).

The pixel unit PXU may be repeatedly arranged along a first diagonal direction IDR1 and a second diagonal direction IDR2. The first diagonal direction IDR1 may refer to a direction inclined at a predetermined acute angle in a clockwise direction with respect to the second direction DR2. The second diagonal direction IDR2 may refer to a direction inclined at a predetermined acute angle in a counterclockwise direction with respect to the second direction DR2. In an embodiment, the first diagonal direction IDR1 and the second diagonal direction IDR2 may be perpendicular to each other.

The auxiliary electrode AE may cover the first emission layer EML1 included in the first pixel area PXA1. The auxiliary electrode AE may have a diamond shape or a rhombus shape. The auxiliary electrode AE may be formed in an individual pattern independently covering each of the first emission layers EML1.

In some embodiments, an area of the first emission layer EML1 may be greater than an area of the second emission layer EML2. The area of the first emission layer EML1 may be greater than an area of the third emission layer EML3. In an embodiment, an area of the third emission layer EML3 may be greater than an area of the second emission layer EML2.

The arrangement and size of the pixel areas illustrated in FIG. 10 are provided as an example and may be appropriately modified in consideration of light-emission properties of the display device.

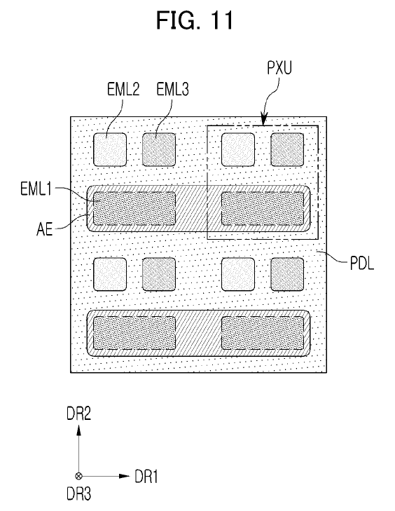

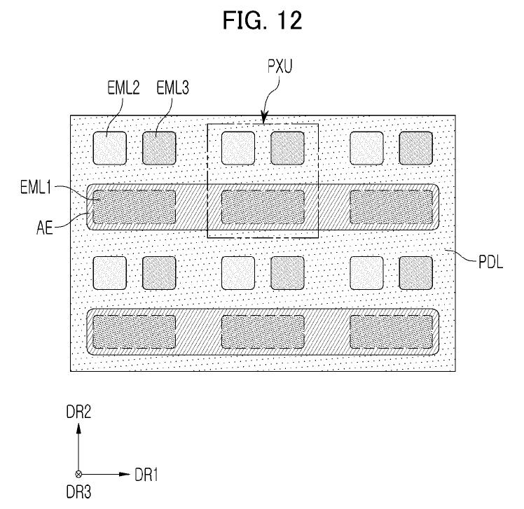

Referring to FIGS. 11 and 12, the auxiliary electrode AE may commonly cover a plurality of the first emission layers EML1. According to embodiments, the auxiliary electrode AE may commonly cover the first emission layers EML1 included in different pixel units PXU.

In an embodiment, as illustrated in FIG. 11, the auxiliary electrode AE may extend in the first direction DR1 and cover the first emission layers EML1 included in two pixel units PXU adjacent to each other in the first direction DR1.

In an embodiment, as illustrated in FIG. 12, the auxiliary electrode AE may extend in the first direction DR1 and cover the first emission layers EML1 included in three pixel units PXU continuously arranged in the first direction DR1.

The number of the first emission layers EML1 covered by the auxiliary electrode AE may be changed to four or more in consideration of resolution and light-emission properties of the display device.

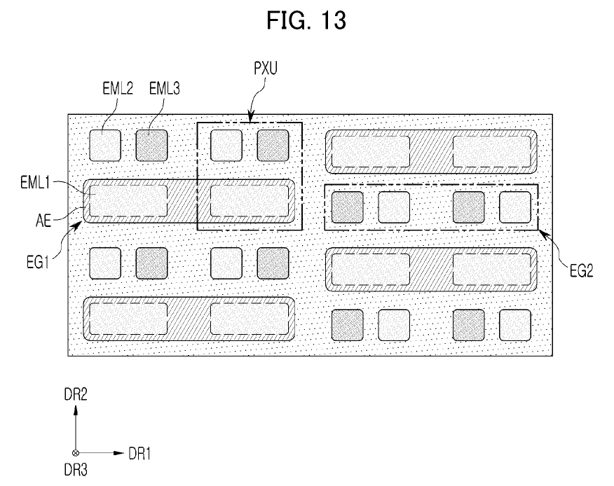

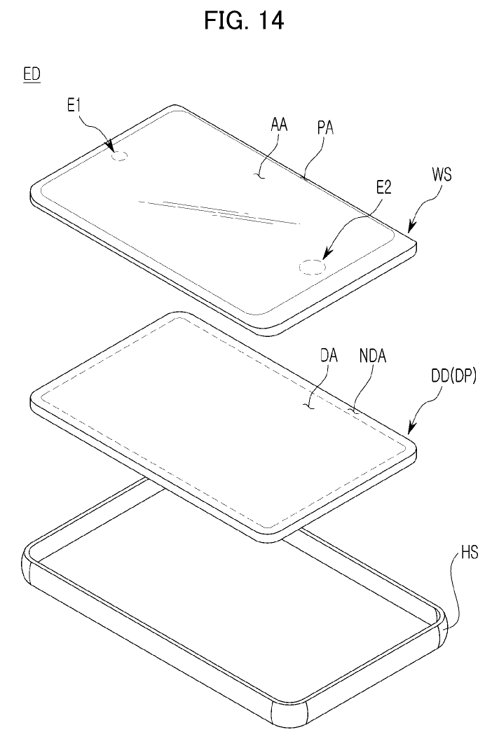

Referring to FIG. 13, as described herein, the auxiliary electrode AE may cover a plurality of the first emission layers EML1. A first emission group EG1 may be defined by the first emission layers EML1 covered by one auxiliary electrode AE.

A second emission group EG2 may be defined by the second emission layers EML2 and the third emission layers EML3 facing the first emission group EG1 in the second direction DR2.

The first emission group EG1 and the second emission group EG2 may be alternately and repeatedly arranged along the first direction DR1. The first emission group EG1 and the second emission group EG2 may be alternately and repeatedly arranged along the second direction DR2.

The first emission group EG1 covered by the auxiliary electrode AE and the second emission group EG2 from which the auxiliary electrode AE is omitted may be alternately distributed, such that balance of color and viewing angle properties may be improved throughout the display device.

FIG. 14 is an exploded perspective view of a display device according to embodiments.

According to embodiments, an electronic device ED may be implemented in the form of a mobile phone (smart phone), a tablet, a personal computer (PC), or the like, including the above-described display device.

Referring to FIG. 14, the electronic device ED may include a window structure WS, a display device DD and a housing HS. The display device DD may include the display panel DP including the transistor structures and the light-emitting element as described herein. The housing HS, the display device DD and the window structure WS may be sequentially stacked in the third direction.

The window structure WS may provide an external display surface recognized by a user of the electronic device such as a mobile phone and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the electronic device ED.

The display device DD or the display panel DP may have a display area DA and a non-display area NDA. The display area DA of the display panel DP may substantially correspond to or overlap the active area AA of the window structure WS.

The non-display area NDA of the display panel DP may substantially correspond to or overlap the peripheral area PA of the window structure WS. In an embodiment, the peripheral area PA may further include a margin area that may not overlap the non-display area NDA.

In some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The housing HS may serve as a supporting frame or a rear housing of the display device DD or the electronic device ED. A cover panel may be disposed between the housing HS and the display panel DP. The housing HS or the cover panel may include a plate (e.g., an SUS plate) that supports the display panel DP. The housing HS or the cover panel may include an elastic body for absorbing shock of the display device DD.

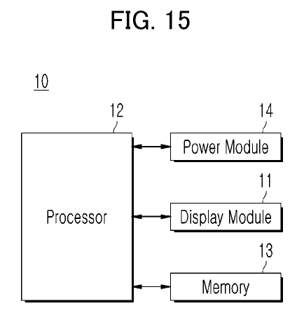

FIG. 15 is a block diagram of an electronic device in accordance with an embodiment.

Referring to FIG. 15, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. In an example in which the processor 12 executes an application stored in the memory 13, an image data signal and/or an input control signal may be transmitted to the display module 11, and the display module 11 may process the received signal, and output image information through a display screen.

The power module 14 may include a power supply module such as a power adapter or a battery device, and a power conversion module that converts a power supplied by the power supply module to a generate power for the operation of the electronic device 10.

At least one of components of the electronic device 10 as described herein may be included in the display device according to the above-described embodiments. In some aspects, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

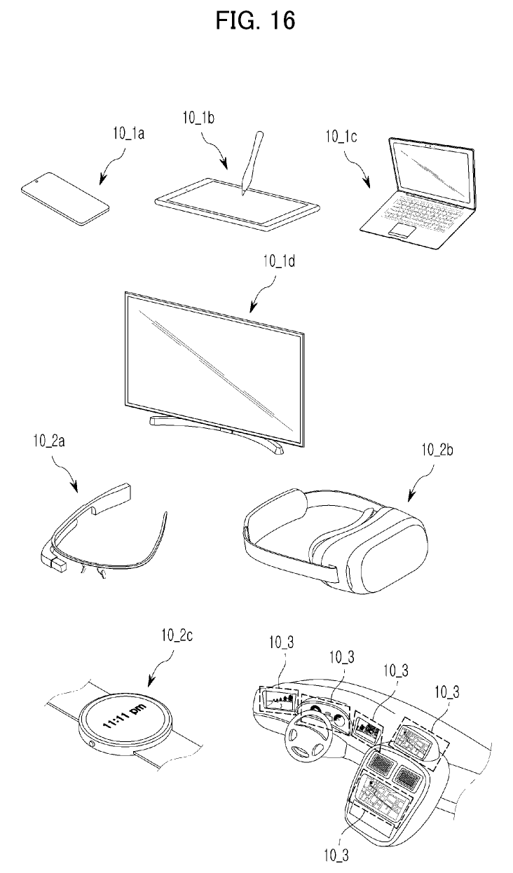

FIG. 16 is a schematic diagram of electronic devices in accordance with various embodiments.

Referring to FIG. 16, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, or the like, a room mirror display, a head-up display, or the like. The electronic device may include a virtual reality glass or an augmented reality glass.

What is claimed is:

1. A display device, comprising:
a base substrate;
a pixel electrode comprising a first pixel electrode, a second pixel electrode , and a third pixel electrode arranged on the base substrate;
emission layers comprising a first emission layer, a second emission layer, and a third emission layer which correspond to different colors and are arranged on the first pixel electrode, the second pixel electrode, and the third pixel electrode, respectively;
an auxiliary electrode selectively covering the first emission layer among the emission layers and covering an entire top surface of the first emission layer, without covering the second emission layer and the third emission layer; and
a counter electrode commonly and continuously covering the first emission layer, the second emission layer, and the third emission layer.

2. The display device of claim 1, wherein the first emission layer, the second emission layer, and the third emission layer are a blue emission layer, a green emission layer, and a red emission layer, respectively.

3. The display device of claim 1, wherein an area of the first emission layer is larger than each of an area of the second emission layer and an area of the third emission layer.

4. The display device of claim 1, wherein:
the counter electrode is a transmissive electrode, and
the auxiliary electrode is a translucent electrode.

5. The display device of claim 4, wherein the auxiliary electrode includes at least one selected from the group consisting of lithium (Li), silver (Ag), magnesium (Mg), aluminum (Al), aluminum-lithium (Al-Li), calcium (Ca), magnesium-indium (Mg-In), silver-magnesium (Ag-Mg), ytterbium (Yb), and silver-ytterbium (Ag-Yb).

6. The display device of claim 1, wherein the auxiliary electrode is disposed between the first emission layer and the counter electrode.

7. The display device of claim 1, wherein the auxiliary electrode is spaced apart from the first emission layer with the counter electrode interposed between the auxiliary electrode and the first emission layer.

8. The display device of claim 1, wherein the auxiliary electrode commonly covers a plurality of the first emission layer.

9. The display device of claim 8, wherein:
a first emission group is defined by the first emission layers commonly covered by the auxiliary electrode, and
a second emission group is defined by the second emission layer and the third emission layer facing the first emission group,
wherein the first emission group and the second emission group are alternately and repeatedly arranged.

10. The display device of claim 1, wherein:
the emission layers comprise a plurality of the first emission layer, the second emission layer, and the third emission layer, each of which has a rhombus shape, and
the auxiliary electrode individually covers each of the first emission layers.

11. The display device of claim 1, wherein:
a resonance light emission is implemented through the first emission layer, and
a non-resonance light emission is implemented through the second emission layer and the third emission layer.

12. A display device, comprising:
a base substrate;
a pixel electrode comprising a first pixel electrode, a second pixel electrode , and a third pixel electrode arranged on the base substrate;
emission layers comprising first emission layers, second emission layers, and third emission layers which correspond to different colors and are arranged on the first pixel electrode, the second pixel electrode, and the third pixel electrode, respectively;
an auxiliary electrode selectively covering the first emissions layers among the emission layers, without covering the second emission layers and the third emission layers, and commonly covering two or more first emission layers among the first emission layers; and
a counter electrode commonly and continuously covering the first emission layers, the second emission layers, and the third emission layers.

13. The display device of claim 12, wherein:
a pixel unit is defined by a first emission layer, a second emission layer, and a third emission layer neighboring each other among the first emission layers, the second emission layers, and the third emission layers,
a plurality of the pixel units are repeatedly arranged, and
the auxiliary electrode extends throughout two or more pixel units of the pixel units .

14. The display device of claim 12, wherein the auxiliary electrode covers an entire top surface of each of the first emission layers.

15. The display device of claim 12, wherein the first emission layers are blue emission layers, the second emission layers are green emission layers, and the third emission layers are red emission layers.

16. The display device of claim 12, wherein:
the counter electrode is a transmissive electrode, and
the auxiliary electrode is a translucent electrode.

17. The display device of claim 12, wherein the auxiliary electrode is disposed between the first emission layers and the counter electrode.

18. The display device of claim 12, wherein the auxiliary electrode is spaced apart from the first emission layers with the counter electrode interposed between the auxiliary electrode and the first emission layers.

19. An electronic device, comprising:
a display device;
a memory; and
a processor executing data included in the memory to control an operation of the display device,
wherein the display device comprises:
a base substrate;
a pixel electrode comprising a first pixel electrode, a second pixel electrode, , and a third pixel electrode arranged on the base substrate;
emission layers comprising a first emission layer, a second emission layer, and a third emission layer which correspond to different colors and are arranged on the first pixel electrode, the second pixel electrode, and the third pixel electrode, respectively;
an auxiliary electrode selectively covering the first emission layer among the emission layers and covering an entire top surface of the first emission layer, without covering the second emission layer and the third emission layer; and
a counter electrode commonly and continuously covering the first emission layer, the second emission layer, and the third emission layer.

20. The electronic device of claim 19, wherein the electronic device comprises virtual reality or augmented reality glasses, a smartphone, a tablet personal computer (PC), a laptop, a television, a desk monitor, smart glasses, a head-mounted display, a smart watch, or a vehicle display.
